(19) United States
(12) Patent Application Publication
(10) Pub. No.: US 2006/0138339 A1
(43) Pub. Date: Jun. 29, 2006

(54) Amorphous selenium detector for tomotherapy and other image-guided radiotherapy systems

(76) Inventors: Guang Y Fang, Madison, WI (US); Thomas R Mackie, Verona, WI (US); David A Spence, Hartland, WI (US); Brent Harper, Prairie du Sac, WI (US)

Correspondence Address: MICHAEL BEST & FRIEDRICH, LLP, 100 E WISCONSIN AVENUE, MILWAUKEE, WI, 53202, US

(21) Appl. No.: 10/537,011

(22) PCT Filed: Nov. 28, 2003
(86) PCT No.: PCT/US03/38168

§ 371 Date: Jan. 13, 2006

Related U.S. Application Data
(60) Provisional application No. 60/429,637, filed on Nov. 27, 2002.

(51) Int. Cl. H01J 47/00; H01L 31/00

(52) U.S. Cl. 250/389; 250/214.1

(57) ABSTRACT

The present invention provides a detector for use in medical and industrial applications for detecting high energy radiation, especially for use in tomotherapy and other image-guided radiotherapy systems. The detector is preferably housed in an enclosure. A plurality of detector elements are installed within the enclosure. The detector elements preferably include a substrate, a readout electrode layer deposited on at least one surface of the substrate, an amorphous selenium layer deposited on at least one surface of the readout electrode layer, and a high voltage electrode layer deposited on at least one surface of the amorphous selenium layer.

### STATEMENT REGARDING FEDERALLY SPONSORED RESEARCH OR DEVELOPMENT

This invention was made with United States Government support awarded by the National Institute of Health (NIH), under Small Business Innovation Research (SBIR) Grant Nos. 1 R43 CA79383-01 and 2R44CA079383-02 The United States Government has certain rights in this invention.

### BACKGROUND OF THE INVENTION

The present invention relates generally to radiation detectors and more particularly to an amorphous selenium (a-Se) detector for use in medical and industrial applications for detecting high energy radiation, especially for use in tomotherapy and other image-guided radiotherapy systems.

Current available detector technologies are not adequate for high energy radiation detection applications. One of the fundamental limitations in high energy x-ray detectors is that the interaction cross-section of high-energy x-rays in matter is significantly reduced. This poses severe problems for megavoltage radiotherapy imaging applications. One either has to settle for poor contrast at a given resolution, or increase the radiation dose to the patient to enhance image quality. The key to improving image quality is to increase the probability of the x-ray interacting in the detector.

The current commercially available solid-state detector designs generally incorporate a layer of converter material in front of the x-ray sensors in order to increase conversion efficiency. Examples of such techniques include adding an intensifying phosphor screen in some scintillator and camera based detectors, or adding a thin layer of high-density material in front of a flat panel amorphous selenium detector system. However, improvements from these prior art systems are quite limited due to the stopping of secondary electrons once the converter material reaches a certain thickness.

None of the current commercially available detectors for radiological (digital radiography or mammography) applications and kilovoltage (kV) computed tomography (CT) applications possess all the desired characteristics for high energy radiation detectors. Currently, commercially available detectors are roughly divided into two categories: flat panel detectors for digital radiography and mammography, and detectors for kV CT scanners. The active sensors used in these detectors are either scintillators such as cesium iodine crystals, or direct charge conversion materials such as amorphous selenium. The-flat panel detectors offer superb spatial resolutions, while the detectors for modern kV CT scanners are designed with extremely high detection efficiencies, typically above 90% for kV x-rays. The flat panel detectors are readout with thin film transistors (TFT), while the CT detectors are typically readout with photo diodes. The sensor thickness of the flat panel detectors is typically less than 0.5 mm, while the sensor thickness of the CT detectors is typically 2 to 3 mm. At radiotherapy energies the conversion efficiency of a flat panel detector is about 0.5%, while the conversion efficiency of a typical CT detector with a 2 mm layer of cadmium tungstate crystals would be about 10%. Neither adequately meets the needs of high energy radiotherapy imaging applications.

Commercially available flat panel detectors are clearly not suitable for high energy or megavoltage (MV) imaging applications for the following reasons:

1) The quantum efficiency is too low because the thickness of the amorphous selenium layer is often too thin, not providing enough converter material.

2) The signal-to-noise ratio and the readout dynamic range, typically 10 bits, are too small for MV imaging applications. As a comparison, typical modern kV readout electronics have a dynamic range of 20 bits.

3) The readout frame rate, typically 30 Hz, is too low, which does not allow the detector system to be readout on a per pulse basis. A related problem is synchronization of the readout electronics. Per pulse acquisition requires synchronization to the linear accelerator (linac) pulse. Furthermore, to effectively collect all the charge from the amorphous selenium detector one needs an electric field of about 10 V/μm which, in this case, requires an applied voltage of 3 kV.

4) The detectors may suffer significant radiation damage after a large amount of radiation exposure. The term “radiation damage” refers to a change in the output signal from a detector, typically becoming smaller, after the detector has withstood a large amount of radiation exposure. It is questionable if the TFT's employed in the readout electronics can survive the level of cumulative radiation exposure in a high energy radiation environment.

5) The pixel sizes are too small for megavoltage applications. At megavoltage energies, the intrinsic blurring due to energetic secondary electrons transport limits achievable spatial resolution. These detectors may also be susceptible to secondary scattering.

The use of amorphous selenium is an x-ray imaging detector is well documented. Significant effort has been devoted to using amorphous selenium for flat panel applications in digital radiography and mammography. Using amorphous selenium in the present invention for megavoltage imaging is a brand new approach.

Amorphous selenium is a direct detector. An amorphous selenium detector converts radiation directly into an electrical signal. Amorphous selenium is a photoconductor that, when exposed to radiation, generates an electrical current proportional to the intensity of the radiation. This can lead to significantly improved detective quantum efficiency (DQE) compared to indirect detectors where the ionization is first converted into light and then back to an electronic signal, thereby introducing various losses in the process. Compared to gas ion chambers, selenium has a density that is thousands of times higher, allowing for much more compact detector designs, especially at high energies. Selenium is a good insulator at room temperature and has a much smaller dark current than semiconductor based detectors. Amorphous selenium is also resistant to radiation damage. All these characteristics are desired for radiotherapy imaging applications.

What is needed is a relatively simple, inexpensive, and high efficiency radiation detector suitable for high-energy tomotherapy and other image-guided radiotherapy imaging applications.

### SUMMARY OF THE INVENTION

The present invention provides a megavoltage radiation detector for medical and industrial applications. The invention also provides a new technique that can improve detective efficiency of a detector for megavoltage x-rays significantly. The concept of incorporating a high density converter into a detector system is applicable regardless of the actual sensors used. This invention should also be applicable to any area where high efficiency in detecting high energy x-rays is required.

A detector assembly in accordance with a first embodiment of the present invention includes an enclosure with a top, bottom, at least two sides, and at least two ends. The detector assembly further includes a plurality of detector elements installed within the assembly. The plurality of detector elements are preferably vertically oriented within the detector assembly. Each of the detector elements preferably includes a substrate, a readout electrode layer deposited on at least one surface of the substrate, an amorphous selenium layer deposited on at least one surface of the readout electrode layer, and a high voltage electrode layer deposited on at least one surface of the amorphous selenium layer. The detector assembly is preferably positioned within a tomotherapy or other image-guided radiotherapy machine such that the x-ray beam from the radiation source is directed downwardly and radially through the detector elements. And an electric field is applied transversely or perpendicularly across the detector elements. The readout electrode layer preferably includes a plurality of conductive strips and gaps that are oriented in various configurations, defining different embodiments that cover the whole radiation fan beam and line up with the x-ray source.

A detector assembly in accordance with a second embodiment of the present invention includes an enclosure with a top, bottom, at least two sides, and at least two ends. The detector assembly further includes a plurality of detector elements installed within the assembly. The plurality of detector elements are preferably arc-shaped and horizontally oriented within the detector assembly. Each of the detector elements preferably includes a substrate, a readout electrode layer deposited on at least one surface of the substrate, an amorphous selenium layer deposited on at least one surface of the readout electrode layer, and a high voltage electrode layer deposited on at least one surface of the amorphous selenium layer. The detector assembly is preferably positioned within a tomotherapy or other image-guided radiotherapy machine such that the x-ray beam from the radiation source is directed downwardly and radially through the detector elements. And an electric field is applied transversely or perpendicularly across the detector elements. Again, the readout electrode layer preferably includes a plurality of conductive strips and gaps that are oriented in various configurations, defining different embodiments that cover the whole radiation fan beam and line up with the x-ray source.

The present invention also contemplates a method of fabricating a megavoltage radiation detector.

The present invention provides a detector assembly that has significantly better sensitivity in megavoltage applications. The detector readout of the present invention is synchronized with the x-ray pulses. It is also possible to readout signals on a pulse-by-pulse basis. The detector assembly of the present invention also has good performance under high radiation exposure rate and can be used in a radiotherapy environment without suffering significant radiation damage or deterioration in performance.

The present invention has applications in tomotherapy systems, where imaging with the tomotherapy beams (the energy, intensity and other operating parameters of the beam can vary) is performed. The detection efficiency of the x-ray beams with the present invention is significantly improved, and thus the ability of resolving the objects is also significantly improved. The imaging functions in a tomotherapy system include pre-treatment imaging for patient registration, in-treatment dynamic imaging for imaging guidance of the treatment, and post treatment imaging for dose reconstruction and treatment verification.

The present invention may also be applied to portal imaging in conventional intensity modulated radiotherapy and other conventional radiotherapy where detecting high energy x-ray beams (energy above 1 MeV) and imaging of the patient with the radiotherapy beams are necessary or beneficial. In these types of applications the image device is placed post-patient in a radiotherapy system where imaging with the radiotherapy beam is performed for the purpose of verifying the setup of the treatment delivery device and operation of the treatment delivering system. The imaging mode can be simple projection imaging, similar to the x-ray films, or it can be tomography imaging reconstruction techniques to derive 3-D information of the patient. As an example, the detector of the present invention may be easily adapted to standard C-arm gantry medical accelerators, providing these units with the capability of CT imaging. Used in portal imaging, the detector of the present invention provides tremendous improvement to image quality due to orders of magnitude improvement in detective efficiency.

It should be noted that the detector of the present invention works just as well for kV CT applications, even though the longitudinal length, along the beam direction, of the detector is a bit excessive. However, the detector of the present invention is extremely attractive for dual energy imaging applications.

The detector assembly of the present invention not only offers superior performance in megavoltage applications but also offers great potential for savings in tomotherapy system manufacturing costs. The process of manufacturing detector elements and the mechanical assembly is much simplified, lowering cost. The main cost savings of the detector system is the electronics, which are also much simpler than prior art systems since the amplitude of the signals in the present invention are much larger.

The detector design of the present invention may also find industrial applications such as defect detection where manufactured items such as cast auto-parts or airplane parts are imaged with high energy x-ray beams for detecting internal materialistic or structural defects. Because of the radiological thickness of these parts, high energy x-rays are necessary to penetrate through the objects being imaged. Conventional detectors are limited in detection efficiency, leading to poor image qualities. The present invention provides a detector with improved image and spatial resolution. Spatial resolution is critical to detect small imperfections in these parts. Other industrial applications for the present invention include detection of foreign objects in food packages and imaging of live trees to ensure quality of lumber before making decisions to cut down a tree in the lumber industry.

The detector of the present invention may also find potential applications in many areas where fast and efficient detection of high energy x-rays are needed. One example is homeland security such as port inspection, including reliably inspecting large pieces of luggage and other goods from ships, airplanes, and trucks requiring penetrating power and spatial resolution. Current prior art imaging devices used for border and port inspections are mostly low energy x-ray machines and are incapable of penetrating materially thick containers. Therefore, high energy x-ray detectors of the present invention may make significant contributions in homeland security. Other areas of security-related applications include inspection of airport baggage, inspection of nuclear waste, and inspection of other large size containers, requiring high energy x-rays.

The following is summary of the features of the detector system of the present invention:

1) The detector provides high detective efficiency above 50% at tomotherapy energies, about 2 MeV in mean energy. This requirement forms the basis of attaining good spatial and contrast resolution. As a comparison, older Xe gas detectors for kV CT scanners, about 60 KeV in mean energy, operate with efficiencies on the order of 70% while modern solid-state detectors operate with efficiencies greater than 95%. Prior art portal image detectors used at MV energies only have efficiencies on the order of 1%.

2) The detector is capable of withstanding high intensity radiation exposure and is able to be exposed to a substantial amount of accumulated exposure without suffering significant deterioration in performance. A typical clinic facility accumulates about 100 to 200 kGy to the detector in a year. Typical dose rates are 3 Gy per minute.

3) The detector is capable of operating in a fast pulsed environment with a typical repetition rate of about 300 Hz and is able to read out every pulse. The afterglow is small and stable and can be reliably correctable when necessary.

4) The detector is two-dimensional with reasonably fine spatial resolution, and covers the largest beam settings in a tomotherapy system.

5) The detector response is linear, stable and immune to general radiation and electromagnetic radiation of a radiotherapy machine. The readout electronics have a large dynamic range, preferably 20 bits.

6) The manufacturing cost for the detector is low compared to prior art detectors.

Various other features, objects, and advantages of the invention will be made apparent to those skilled in the art from the following detailed description.

### BRIEF DESCRIPTION OF THE DRAWINGS

FIG. 1 is a perspective view of an embodiment of a detector assembly in accordance with the present invention;

FIG. 2 is a perspective view of the detector assembly of FIG. 1 with the top of the assembly removed;

FIG. 3 is an enlarged detailed view of an upper corner portion of the assembly of FIG. 2 taken from detail 3 of FIG. 2;

FIG. 4 is a top plan view of an embodiment of a detector element in accordance with the present invention;

FIG. 5 is an enlarged detailed view of a portion of the detector element of FIG. 4 taken from detail 5 of FIG. 4;

FIG. 6 is an enlarged exploded view of the detector element of FIGS. 4 and 5;

FIG. 7 is an enlarged detailed view of an embodiment of a readout electrode layer of the detector element of FIG. 6;

FIG. 8 is an enlarged detailed view of another embodiment of a readout electrode layer of the detector element of FIG. 6;

FIG. 9 is a perspective view of another embodiment of a detector assembly in accordance with the present invention with top, one side, and one end of the assembly removed;

FIG. 10 is a perspective view of the detector assembly of FIG. 9 with portions of the enclosure and dielectric spacers in phantom;

FIG. 11 is a cross-sectional view of the detector assembly of FIGS. 9 an 10 taken along line 11-11 of FIG. 10;

FIG. 12 is an enlarged exploded view of another embodiment of a detector element in accordance with the present invention;

FIG. 13 is an enlarged front plan view of another embodiment of a readout electrode layer of the detector element of FIG. 12;

FIG. 14 is an enlarged detailed view of an embodiment of a readout electrode layer of the detector element of FIG. 12 taken from detail 14 of FIG. 12; and

FIG. 15 is an enlarged detailed view of another embodiment of a readout electrode layer of the detector element of FIG. 12 taken from detail 15 of FIG. 13.

### DETAILED DESCRIPTION OF THE INVENTION

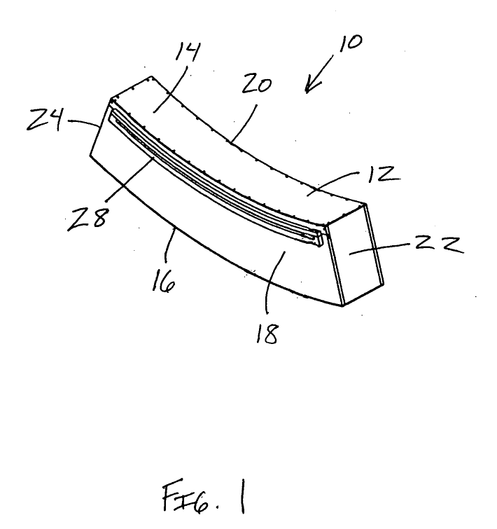

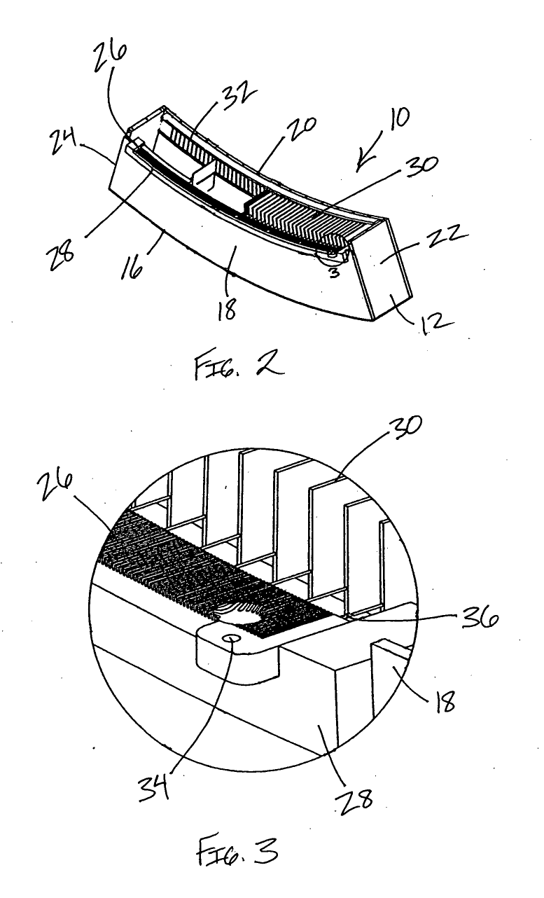

Referring now to the drawings, FIGS. 1-3 illustrate different views of an embodiment of a detector assembly 10 in accordance with the present invention. The detector assembly 10 is preferably housed in an enclosure 12 as shown in FIG. 1. The enclosure 12 is preferably arc-shaped and comprises a top 14, bottom 16, at least two sides 18, 20, and at least two ends 22, 24. A high voltage bus bar 26 extends from one of the sides 18 for connection to a high voltage source (not shown). A first dielectric element 28 preferably extends around and supports the bus bar 26. The top 14 and bottom 16 of the enclosure 12 aid in support and alignment of the detector assembly 10 when installed in tomotherapy and other image-guided radiotherapy systems. FIG. 2 shows the detector assembly 10 of FIG. 1 with the top 14 of the assembly removed. A plurality of detector elements 30 are installed within the assembly 10. A second dielectric element 32 is preferably attached to the upper inside surface of one of the sides 20 opposite the side 18 having the first dielectric element 28 attached thereto for supporting and aligning the detector elements 30 between the first and second dielectric elements. The dielectric elements 28, 32 preferably include alignment features for locating the detector elements 30 within the assembly. In addition to the high voltage bus bar 26 and the plurality of detector elements 30, the enclosure 12 also houses signal conditioning and digitization electronics (not shown) for the assembly. FIG. 3 is an enlarged detailed view of an upper comer portion of the detector assembly 12 shown in FIG. 2 taken from detail 3 of FIG. 2. FIG. 3 shows the first dielectric element 28 supporting the high voltage bus bar 26, a high voltage connection 34 for the high voltage bus bar 26, and a plurality of wire connections 36 from each of the detector elements 30 to the high voltage bus bar 26.

The detector assembly 10 preferably provides a large number of detector elements 30 compared to the current commercially available multi-row kV CT scanner detector systems. The detector elements 30 are preferably vertically oriented within the detector assembly 10. The detector elements 30 are preferably arranged coincidentally with a diverging x-ray beam. The divergence is preferably maintained by the tapering dielectric element 32 on one side of the detector elements. The dielectric elements 28, 30 and the substrate of the detector elements 30 provide electric isolation between neighboring layers of the detector elements.

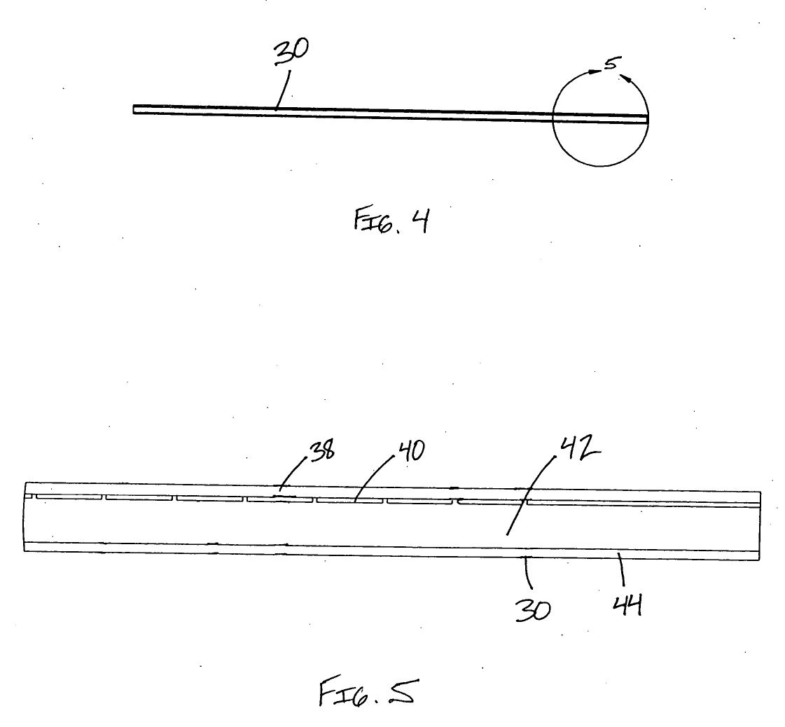

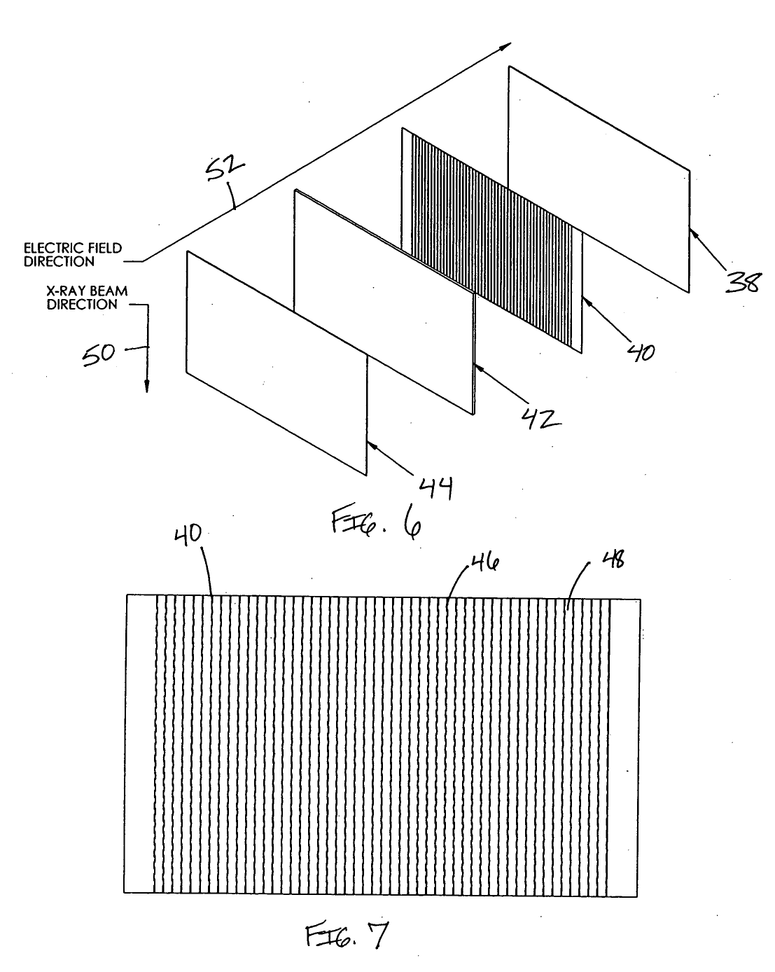

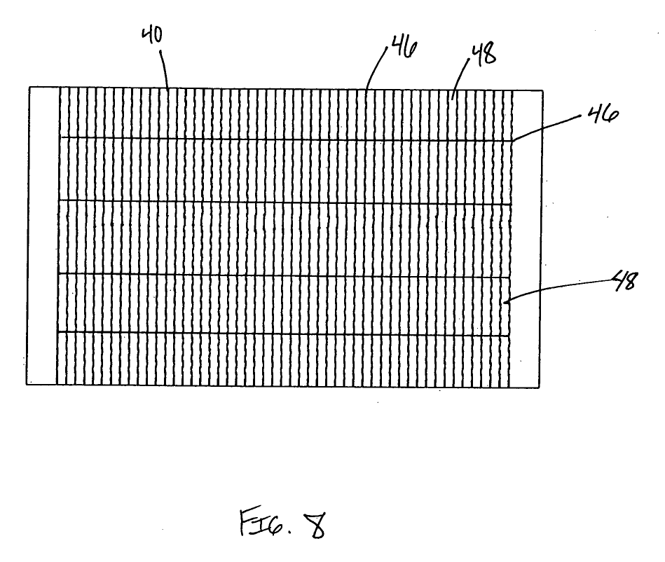

FIGS. 4-6 illustrate an embodiment of a detector element 30 in accordance with the present invention. FIG. 5 is an enlarged detailed view of a portion of the detector element 30 of FIG. 4 taken from detail 5 of FIG. 4. FIG. 6 is an enlarged exploded view of the detector element 30 of FIGS. 4 and 5. The detector element 30 preferably comprises a substrate 38, a readout electrode layer 40 deposited on at least one surface of the substrate 38, an amorphous selenium layer 42 deposited on at least one surface of the readout electrode layer 40, and a high voltage electrode layer 44 deposited on at least one surface of the amorphous selenium layer 42. Each of these layers is preferably deposited using vacuum deposition/evaporation or other suitable method. The substrate 38 is preferably made of a glass material or other insulating material. The readout electrode layer 40 preferably comprises a plurality of conductive strips or lines 46 deposited on at least one surface of the substrate as shown in FIG. 7. There are gaps or open spaces 48 between the conductive strips or lines 46, again as shown in FIG. 7. The amorphous selenium layer 42 preferably comprises a uniform and continuous amorphous selenium material vapor deposited over the charge collection electrode layer 40. The high voltage electrode layer 44 is preferably of tungsten or other highly conductive material that can withstand high voltages.

As shown in FIG. 6, the x-ray beam 50 from the radiation source (not shown) is directed downwardly and radially through the detector elements 30. An electric field 52 is applied transversely or perpendicularly across the detector elements 30. Therefore, charge transport is constrained along the vertical field lines, significantly reducing lateral information spread. This means that the detector output closely matches the input radiation.

In a preferred embodiment, each detector element forms a pixel projecting to 1×1 mm² in area at the iso-center. The detector element is preferably fabricated from a single-sided substrate of about 0.25 mm thick. One side of the substrate preferably includes readout strips along the x-ray beam direction. The readout strips are preferably about 1.4 mm wide separated from each other by a gap about 0.1 mm wide. The length of the detector element along the beam direction is preferably about 5 cm to achieve 50% quantum efficiency. The height of the substrate is preferably about 8.5 cm. An amorphous selenium layer of approximately 1 mm thick is preferably deposited on top of the readout strips. A high voltage electrode tungsten layer of about 200 μm is preferably attached to the other side of the amorphous selenium layer, opposite the side deposited on top of the readout strips, forming the high voltage electrode layer. Care is preferably taken to ensure good conducting interface between the selenium and the tungsten surfaces. The high voltage electrode tungsten layer also serves as a converter and septa for rejecting very low energy photons resulted from secondary interactions in and upstream of the detector system. The x-ray beam enters the detector from the top as indicated in FIG. 6. The electric field lines point across the layers of the detector elements. Positive charges or holes are created in the tungsten or selenium from a primary photon interaction that is driven by the applied electric field towards the conducting readout strips on the substrate where they are collected. Each readout conducting strip on the substrate represents one detector. At a modest thickness of the amorphous selenium layer, less than 1 mm, and high electric field, approximately 10 V/μm, the spread of charge in the vertical direction, perpendicular to the electric field direction, is expected to be small, less than 100 μm. Therefore, the separation between the neighboring electrodes is preferably 100 μm. The wide readout strips, preferably 5 mm each, at the outer edges of the substrate are guard electrodes, which are preferably grounded to reduce electronic noise on the charge collection electrodes. Since the energy of the primary photon is high, the number of electrons per interaction will be large. The detector therefore, can probably be operated at a lower electric field, on the order of 5 V/μm. This simplifies the complexity of the detector and the data acquisition system of the present invention.

FIG. 7 is an enlarged detailed view of an embodiment of a readout electrode layer of the detector element of FIG. 6. FIG. 8 illustrates an enlarged detailed view of another embodiment of a readout electrode layer of the detector element of FIG. 6. The readout electrode layer of FIG. 8 includes additional readout strips and gaps formed perpendicular to the original readout strips and gaps and perpendicular to the x-ray beam direction. This provides for more detailed and accurate detection of radiation.

An analysis of the required tolerances is important to optimize cost and performance of the present invention. The resolution of the photoetching of the readout electrode layer is preferably maintained to 5 μm. The thickness of the amorphous selenium layer is preferably maintained to 50 μm. These tolerances will result in interaction volume variation of about 5%. This will not affect the performance because the signal from each detector element will always be normalized to the signal in that detector element in the absence of a patient on a in tomotherapy and other image-guided radiotherapy system. The thickness of the high voltage electrode layer is preferably maintained to 25 μm. Local or global variations in the electrode layer or the substrate will not affect performance of the present invention because the thickness of the layers and the thickness of the separation will not influence the amount of charge collected, and small variations can be normalized out in the same fashion as for the active detector volume. The dielectric element thickness tolerance is preferably maintained to 2 μm. Random variations will not affect performance and systematic variations will be evident after all the layers are stacked and adjustments made. The tolerances of the components and layers can be easily maintained by modern machining and photoetching technology.

The detector elements will be read out individually for every input radiation pulse with 16 bit integration analog-to-digital converters (ADCs). The digitizers of the ADCs are preferably equipped with a range selection bit to handle the big difference in the amplitudes of the output signals between the image and treatment mode of the tomotherapy or other image-guided radiotherapy machine, leading to an effective ADC range of 20 bits. At a typical linac repetition rate of 300 Hz, the data rate will be 25 k×2B×300/s=15 MB/second, a fairly modest rate compared to modern kV CT devices. As stated above, the analog outputs from the detection elements are preferably multiplexed to digitizers. At the typical tomotherapy linac repetition rate, a level of multiplexing of 500 to 1000 is possible, which reduces the number of digitizers from 25 to 50. This helps to reduce the manufacturing cost of the detector assemblies of the present invention substantially.

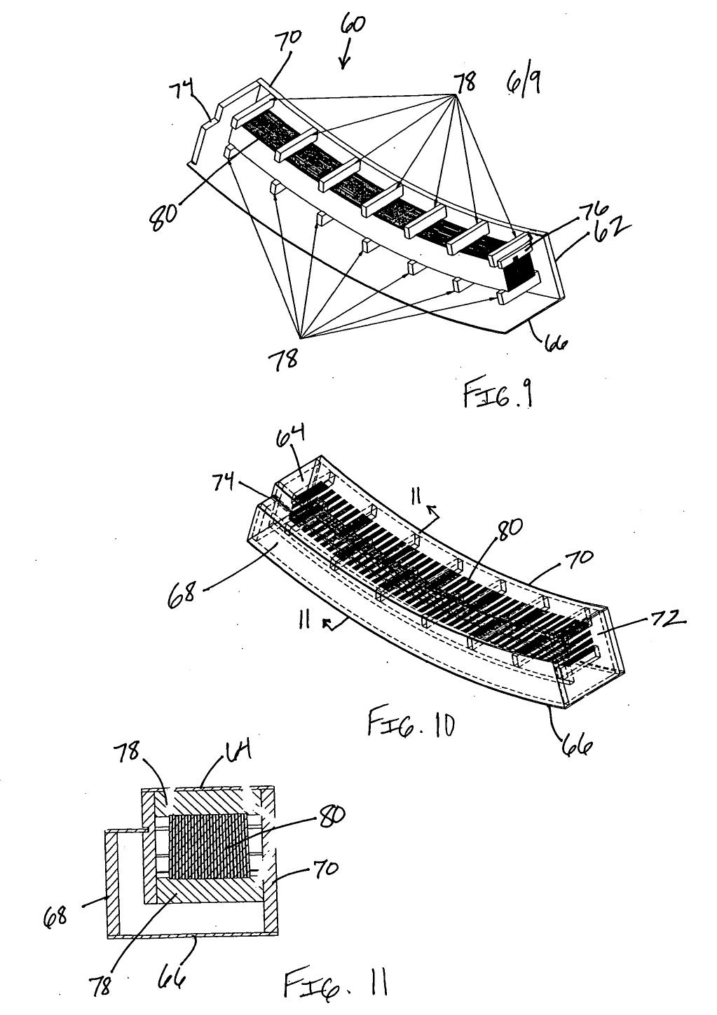

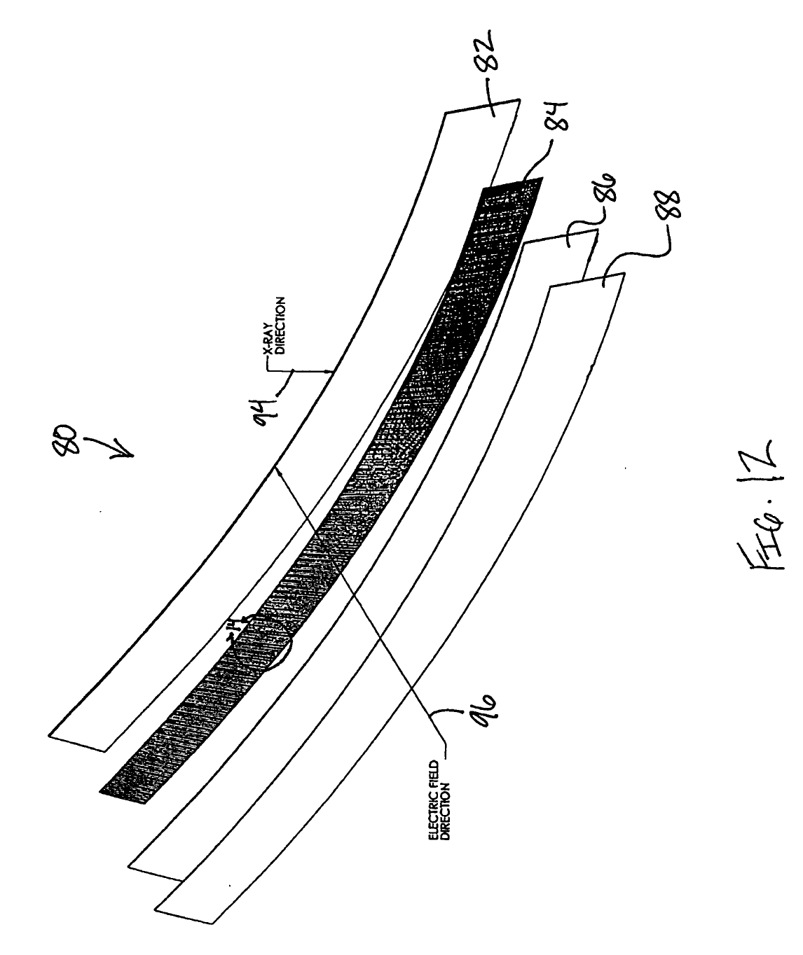

FIGS. 9-11 illustrate different views of another embodiment of a detector assembly 60 in accordance with the present invention. FIG. 9 is a perspective view of the detector assembly 60 with the top, one side, and one end of the assembly removed. FIG. 10 is a perspective view of the detector assembly 60 with portions of the enclosure and dielectric spacers in phantom. FIG. 11 is a cross-sectional view of the detector assembly 60 taken along line 11-11 of FIG. 10.

The detector assembly 60 is preferably housed in an enclosure 62. The enclosure 62 is preferably arc-shaped and comprises a top 64, bottom 66, at least two sides 68, 70, and at least two ends 72, 74. A high voltage connection 76 extends from at least one end of the detector elements 80 for connection to a high voltage source (not shown). A plurality of detector elements 80 are installed within the assembly 60. The detector elements 80 are also preferably arc-shaped and oriented horizontally within the detector assembly. A plurality of upper and lower dielectric elements 78 are positioned on the top and bottom of the detector elements 80 for supporting and aligning the detector elements 80 within the detector assembly 60. The detector elements 80 are preferably aligned towards the radiation source (not shown). The enclosure 62 further includes signal conditioning and digitization electronics (not shown) for the assembly.

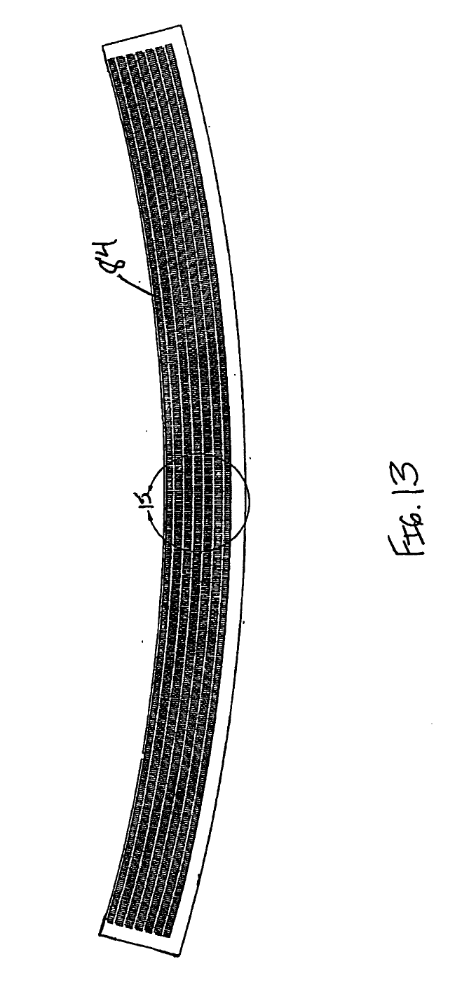

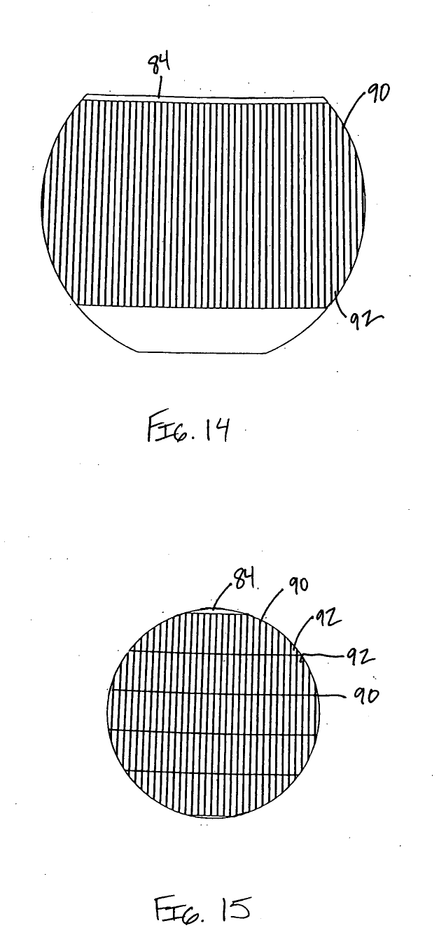

FIG. 12 illustrates another embodiment of a detector element 80 in accordance with the present invention. The detector element 80 preferably comprises a substrate 82, a readout electrode layer 84 deposited on at least one surface of the substrate 82, an amorphous selenium layer 86 deposited on at least one surface of the readout electrode layer 84, and a high voltage electrode layer 88 deposited on at least one surface of the amorphous selenium layer 86. Each of these layers is preferably deposited using vacuum deposition/evaporation, photoetching, or other suitable method. The substrate 82 is preferably made of a glass material or other insulating material. The readout electrode layer 84 preferably comprises a plurality of conductive strips or lines 90 deposited on at least one surface of the substrate as shown in FIG. 14. There are gaps or open spaces 92 between the conductive strips or lines 90, again as shown in FIG. 14. The amorphous selenium layer 86 preferably comprises a uniform and continuous amorphous selenium material vapor deposited over the charge collection electrode layer 84. The high voltage electrode layer 88 is preferably of tungsten or other highly conductive material that can withstand high voltages. The substrate 82 provides electric isolation between neighboring layers of the detector elements.

As shown in FIG. 12, the x-ray beam 94 from the radiation source (not shown) is directed downwardly and radially through the detector elements 80. An electric field 96 is applied transversely or perpendicularly across the detector elements 80. Each detector element 80 consists of a plurality of different layers. Each layer will have a certain number of channels that cover the whole radiation fan beam in that plane. The substrate is preferably arranged to form an arc with traces lining up and converging to the x-ray source. The length of the traces will be optimized for maximum DQE. FIG. 13 is an enlarged front plan view of another embodiment of the readout electrode layer 84 of the detector element of FIG. 12.

FIG. 14 is an enlarged detailed view of an embodiment of a readout electrode layer of the detector element of FIG. 13. FIG. 15 illustrates an enlarged detailed view of another embodiment of a readout electrode layer of the detector element of FIG. 13. The readout electrode layer of FIG. 15 includes additional readout strips and gaps formed perpendicular to the original readout strips and gaps and perpendicular to the x-ray beam direction. This provides for more detailed and accurate detection of radiation.

As shown in FIG. 15, the reading out of the signals from each electrode are segmented along the beam direction of each channel. Each segment is attached to separated electronics and readout separately. By correlate the signals from different segments, information on dose deposition in the longitudinal direction (along the x-ray direction), thus the energy of the x-rays can be extracted.

In the above embodiments the traces of the electrodes can have a different pitch and width, depending on the need of the specific applications. The total number of channels in the vertical and horizontal directions can vary depending on the application.

While the invention has been described with reference to preferred embodiments, it is to be understood that the invention is not intended to be limited to the specific embodiments set forth above. It is recognized that those skilled in the art will appreciate that certain substitutions, alterations, modifications, and omissions may be made without departing from the spirit or intent of the invention. Accordingly, the foregoing description is meant to be exemplary only, the invention is to be taken as including all reasonable equivalents to the subject matter of the invention, and should not limit the scope of the invention set forth in the following claims.

We claim:

1. A radiation detector comprising:
a radiation source directing radiation along a propagation axis;
a detector positioned to receive the radiation, the detector including a plurality of sheets oriented to extend substantially along the propagation axis and spaced transversely across the axis to define a plurality of axially extending detector volumes, the sheets receive radiation longitudinally and generate high-energetic electrons exiting the material into the detector volumes; and
detection means detecting negatively and positively charged high-energetic particles liberated into the detector volumes to provide for substantially independent signals.

2. The radiation detector of claim 1 wherein the detection means is an amorphous selenium detector.

3. A megavoltage radiation detector comprising:
a radiation source directing megavoltage radiation along a propagation axis;
a detector positioned to receive the radiation, the detector including a plurality of sheets oriented to extend substantially along the propagation axis and spaced transversely across the axis to define a plurality of axially extending detector volumes, the sheets receive radiation longitudinally and generate high-energetic electrons exiting the material into the detector volumes; and
detection means detecting negatively and positively charged high-energetic particles liberated into the detector volumes to provide for substantially independent signals.

4. A method of fabricating a megavoltage radiation detector, the method comprising the steps of:
depositing a plurality of readout electrodes on at least one surface of a substrate;
depositing an amorphous selenium layer on at least one surface of the readout electrodes; and
depositing a high voltage electrode layer on at least one surface of the amorphous selenium layer.
